(19) United States
(12) Patent Application Publication
(10) Pub. No.: US 2010/0095188 A1
(43) Pub. Date: Apr. 15, 2010

(54) APPARATUS AND METHOD FOR DETECTING AND CORRECTING ERRORS IN CONTROL CHARACTERS OF A MULTIMEDIA INTERFACE

(75) Inventor: Wolfgang ROETHIG, San Jose, CA (US)

Correspondence Address: MYERS WOLIN, LLC, 100 HEADQUARTERS PLAZA, North Tower, 6th Floor, MORRISTOWN, NJ, 07960-6834, US

(73) Assignee: TRANSWITCH CORPORATION, Shelton, CT (US)

(21) Appl. No.: 12/248,398

(22) Filed: Oct. 9, 2008

(51) Int. Cl. H03M 13/05; G06F 11/07

(52) U.S. Cl. 714/777; 714/752; 714/E11.021

(57) ABSTRACT

An apparatus and method for detecting and correcting errors in control characters of a multimedia interface. The apparatus comprises a hamming distance filter for detecting and correcting bits errors in a first subset of bits of an input control character including M bits; a glitch filter for detecting and correcting a second subset of bits being a complementary subset of bits of the control character; and an character alignment unit for detecting and correcting misalignment errors between the corrected first subset of bits and the corrected second subset of bits.

### TECHNICAL FIELD

This invention generally relates to electronic display device connectivity.

### BACKGROUND OF THE INVENTION

The high-definition multimedia interface (HDMI™) is a licensable compact audio/video connector interface for transmitting uncompressed digital streams. The HDMI connects digital audio/video (or multimedia) sources (e.g., a set-top box, a DVD player, a personal computer, a video game console, etc.) to a compatible digital audio device and/or video monitor such as a digital television. In contrast to consumer analog standards the HDMI enforces digital rights management (DRM) on transmitted media. The HDMI is fully described in the HDMI™ Specification version 1.3 published on Jun. 22, 2006, incorporated herein by reference in its entirety merely for the useful understanding of the background of the invention.

A block diagram of a HDMI link 100 is shown in FIG. 1. A multimedia source 110 transmits high speed data using transition minimized differential signaling (TMDS) characters. The TDMS characters encapsulate video, audio, and auxiliary data and are carried over three TDMS channels 130-0, 130-1, and 130-2. A clock, typically running at the video pixel rate, is transmitted on a clock channel 140 and is used by the multimedia sink 120 as a frequency reference for data recovery on the three TMDS channels collectively referenced as 130. In addition, configuration, system-level control, management and status information is exchanged between the multimedia source 110 and the multimedia sink 120. The system-level control includes display data channel (DDC) and consumer electronics control (CEC), which are transmitted over channels: SCL 150, SDA 160, and CEC 170. A standard HDMI interface further includes a hot-plug detect (HPD) signal 180 which originates at the sink 120.

TDMS characters are transported at three different time periods: a video data period, a data island period, and a control period. During the video data period, the pixels of an active video line are transmitted. During the data island period, which occurs during the horizontal and vertical blanking intervals, audio and auxiliary data are transmitted within a series of packets. Control characters are transported during the control period, which occurs between video and data island periods. On the TDMS channel 130-0, control characters are used to encode VSYNC and HSYNC signals, while on channels 130-1 and 130-2, control characters encode preambles for video and packet data periods and indicate encryption status for high-bandwidth digital content protection (HDCP).

Obviously, an error in the control characters can result in fatal consequences. Specifically, an error in a control character on channel 130-0 disturbs the video timing, possibly resulting in a lost video line or an entirely lost video frame. An error on channels 130-1 or 130-2 can indicate a wrong encryption status, resulting in loss of the HDCP link, requiring HDCP re-authentication. In this case, many video frames are lost. If a video frame is lost due to erroneous VSYNC, the HDCP link will also be lost.

The HDMI link is assumed to be a reliable transport medium, and thus no error correction solutions exist for detecting and correcting erroneous control characters. However, in fact, control characters include error bits which are transmitted from the multimedia source 110 to sink 120. Therefore, solutions for correcting such bits are required. In addition, having solutions for detecting and correcting errors would enable the relaxing of the HDMI specification, thereby providing for the design of low cost HDMI cables and connectors.

### SUMMARY OF THE INVENTION

Certain embodiments of the invention include an apparatus for detecting and correcting errors in control characters of a multimedia interface. In one embodiment, an apparatus comprises a hamming distance filter for detecting and correcting bits errors in a first subset of bits of an input control character including M bits, and a glitch filter for detecting and correcting a second subset of bits being a complementary subset of bits of the control character.

Certain embodiments of the invention also include a method for detecting and correcting errors in control characters of a multimedia interface. The method comprises detecting and correcting bits errors in a first subset of bits of an input control character including M bits, and detecting and correcting a second subset of bits being a complementary subset of bits of the input control character.

Certain embodiments of the invention further include a computer readable medium having stored thereon a computer executable code causing a computer to perform the process of detecting and correcting errors in control characters of a multimedia interface. The process comprises detecting and correcting bits errors in a first subset of bits of an input control character including M bits, and detecting and correcting a second subset of bits being a complementary subset of bits of the input control character.

### BRIEF DESCRIPTION OF THE DRAWINGS

The subject matter that is regarded as the invention is particularly pointed out and distinctly claimed in the claims at the conclusion of the specification. The foregoing and other objects, features and advantages of the invention will be apparent from the following detailed description taken in conjunction with the accompanying drawings.

FIG. 1 is a block diagram of an HDMI link.

FIG. 2 is a block diagram of an apparatus for detecting and correcting errors in control characters of a multimedia interface.

FIG. 3 is a schematic diagram of a glitch filter.

FIG. 4A is a block diagram of a 1-clock-cycle glitch filter constructed in accordance with an embodiment of the invention.

FIG. 4B is a block diagram of a 2-clock-cycle glitch filter constructed in accordance with an embodiment of the invention.

FIG. 5 is a block diagram of a character alignment detection unit constructed in accordance with an embodiment of the invention.

FIG. 6 is a flowchart describing a method for detection and correcting control character errors implemented in accordance with an embodiment of the invention.

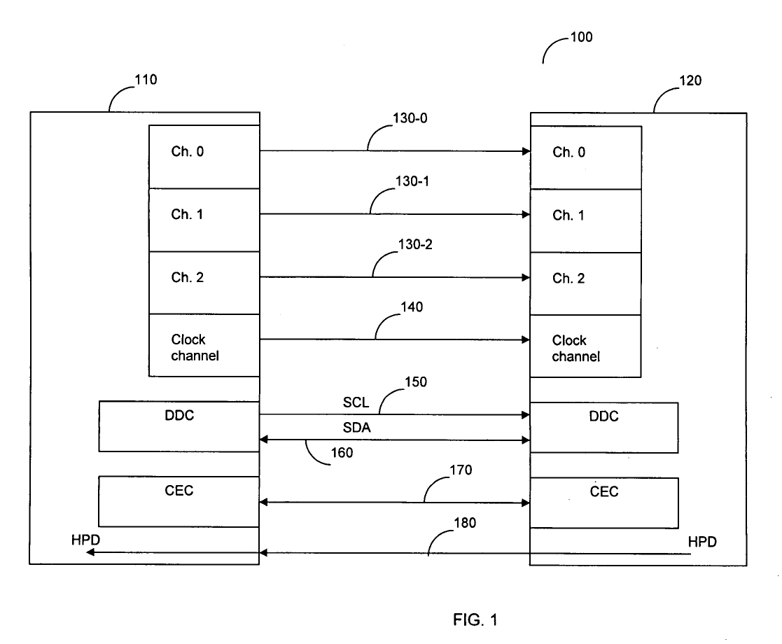

### DETAILED DESCRIPTION OF THE INVENTION

It is important to note that the embodiments disclosed by the invention are only examples of the many advantageous uses of the innovative teachings herein. In general, statements made in the specification of the present application do not necessarily limit any of the various claimed inventions. Moreover, some statements may apply to some inventive features but not to others. In general, unless otherwise indicated, singular elements may be in plural and vice versa with no loss of generality. In the drawings, like numerals refer to like parts through several views.

In accordance with one embodiment of the principles of the present invention, errors in control characters are detected and corrected by analyzing the patterns of the characters. The HDMI standard defines only 4 TDMS character codes, each having 10 binary bits. The 9 least significant bits (LSBs) of the characters are based on 2 different patterns: 101010100 and 010101011. In addition, a control character cannot change its value every clock cycle. The TDMS control characters are provided in Table 1.

TABLE 1
10-bit control character

| | |
|---|---|
| 1 | 0b1101010100 |
| 2 | 0b0010101011 |
| 3 | 0b0101010100 |
| 4 | 0b1010101011 |

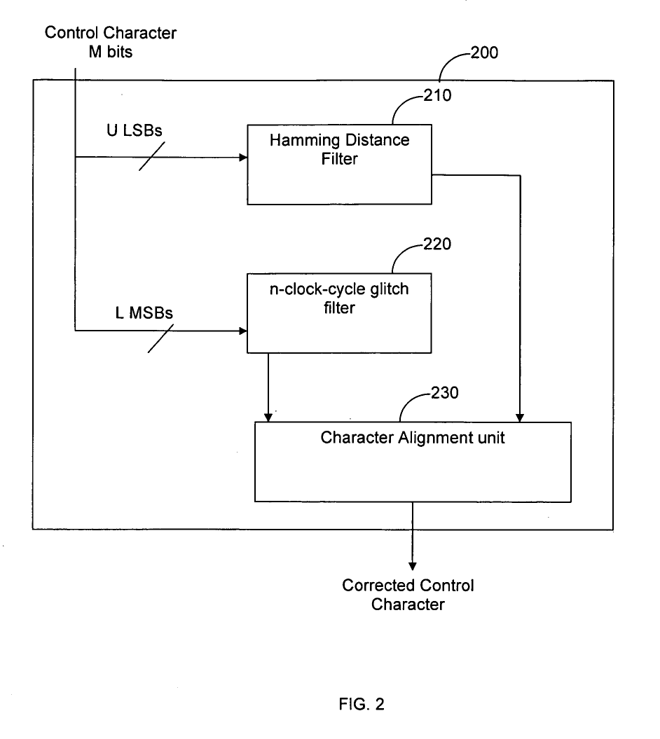

FIG. 2 shows an exemplary and non-limiting block diagram of an apparatus 200 utilized for correcting errors in control characters in multimedia interface constructed in accordance with an embodiment of the invention. The apparatus 200 comprises a hamming distance filter 210, a glitch filter 220, and a character alignment unit 230. The apparatus 200 receives a control character and checks if it includes errors, and if so outputs a corrected control character. In one embodiment of the invention, the input characters are one of the TDMS control characters shown in Table 1 above.

The operation of the apparatus 200 will be described with a reference to a specific embodiment where the control characters are the TDMS characters shown in Table 1. However, one of ordinary skill in the art can easily adapt the teachings described herein to detect and correct characters having different patterns from those shown in Table 1.

The apparatus 220 distinguishes one control character from the other. With this aim, the hamming distance filter 210 receives 9 LSBs of an input control character. The hamming distance between two characters is defined as the number of different bits in each character. As each bit in the 9-LSB-pattern of two characters is different, the hamming distance between two characters is 9. If a received character does not match the characters, the received character is replaced by one of the two patterns having the smallest hamming distance to an input character. If the number of erroneous bits is 4 or less, the replacement pattern will be correct. Therefore, the number of bit errors that can be corrected and detected is 4. The hamming distance is defined as the number of bit errors that transformed one character to another. The hamming distance filter 210 matches the input 9 LSBs to two possible 9-LSB-patterns, and determines the minimum hamming distance of each of these patterns. The input 9 LSBs are corrected to match the pattern from which the distance is minimal. For example, if the input 9 LSBs are 101001011, the hamming distance from the 9-LSB-pattern of the first and third character, i.e., 101010100 is 5 (the different bits are underlined and the hamming distance from the 9-LSB-pattern of the second and fourth character, i.e., 010101011 is 4. Therefore, the corrected output 9 LSBs will be 010101011.

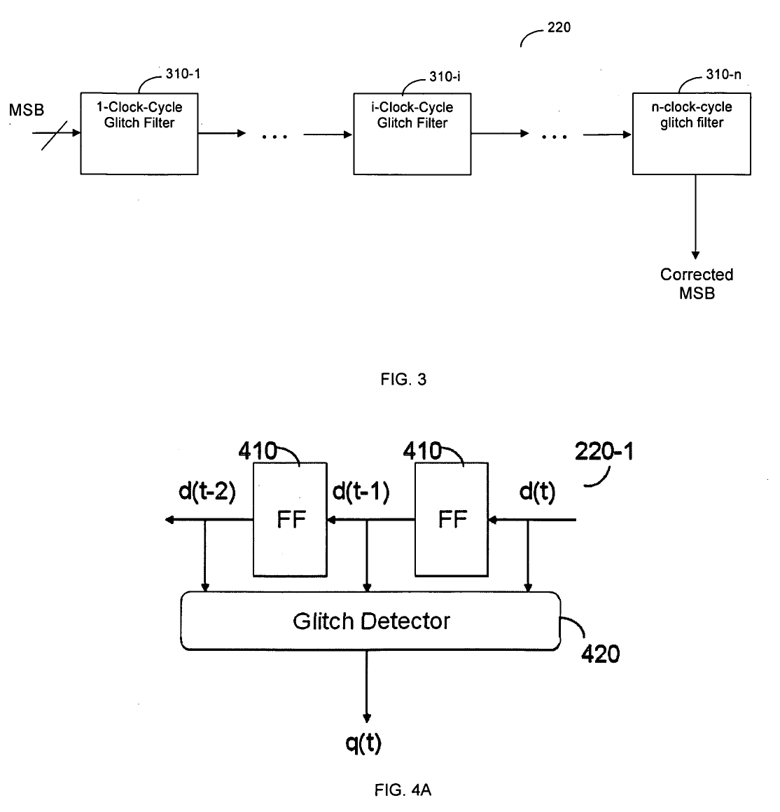

Errors in the MSB are detected and corrected using the glitch filter 220 and the character alignment unit 230. Specifically, the glitch filter 220 is capable of detecting spurious MSB transition during ‘n’ clock cycles (where ‘n’ is an integer equal to or greater than 1). As illustrated in FIG. 3, the glitch filter 220 can be constructed using ‘n’ glitch filters 310-1 through 310-n connected in cascade to detect erroneous MSB during different consecutive clock cycles. For example, the first filter 310-1 operates during 1 clock cycle while the i-th cascaded filter 310-i detects errors during i consecutive clock cycles. In a preferred embodiment the glitch filter 220 is of 2 clock cycles (i.e., includes 1-clock cycle and 2-clock-cycle filters) as the probability to detect spurious MSB transition during 3 clock cycles is relatively low.

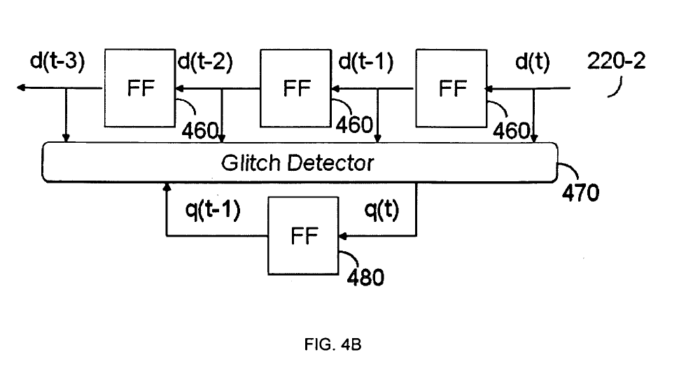

FIG. 4A shows a non-limiting block diagram of 1-clock-cycle glitch filter 220-1 constructed in accordance with an embodiment of the invention. The glitch filter 220 includes two cascaded flip-flops (FF) 410 and a glitch detector 420. The detector 420 determines if an error occurs in the MSB and outputs a corrected bit q(t) if such error was detected. An input bit d(t) is spurious, if the binary values of the inputs d(t), d(t-1) and d(t-2) are different. These inputs reflect the values of the MSB, during a clock transit, at three different times, t, t-1, and t-2. The corrected MSB is the value of the input d(t). In one embodiment of the invention the glitch detector 420 outputs the corrected bit according to the following table.

TABLE 2

| d(t − 2) | d(t − 1) | d(t) | q(t) | results |
|---|---|---|---|---|
| 0 | 0 | 0 | 0 | pass |
| 0 | 0 | 1 | 0 | pass |
| 0 | 1 | 0 | 0 | suppress glitch |
| 0 | 1 | 1 | 1 | pass |
| 1 | 0 | 0 | 0 | pass |
| 1 | 0 | 1 | 1 | suppress glitch |
| 1 | 1 | 0 | 1 | pass |
| 1 | 1 | 1 | 1 | pass |

FIG. 4B shows a non-limiting block diagram of 2-clock cycles glitch filter 220-2 constructed in accordance with an embodiment of the invention. The glitch filter 220-2 includes three cascaded flip-flops 460 and a glitch detector 470, which its output q(t) its coupled to a flip-flop 480. The detector 470 determines if an error occurs in the MSB and outputs a corrected bit q(t) if such error was detected. An input bit d(t) is spurious if its value or the value of d(t-1) during a clock transit is unknown. The corrected MSB is the value of either the input d(t) or d(t-1) and may be determined according to the following true table:

TABLE 3

| d(t − 3) | d(t − 2) | d(t − 1) | d(t) | q(t) | results |
|---|---|---|---|---|---|
| 0 | 0 | 0 | ? | 0 | pass |
| ? | 0 | 0 | 0 | 0 | pass |
| 1 | 0 | 1 | ? | 1 | suppress glitch |
| 1 | 0 | ? | 1 | 1 | suppress glitch |
| 0 | 0 | 1 | ? | q(t − 1) | hold |
| 1 | 1 | 1 | ? | 1 | pass |
| ? | 1 | 1 | 1 | 1 | pass |
| 0 | 1 | 0 | ? | 0 | suppress glitch |
| 0 | 1 | ? | 0 | 0 | suppress glitch |
| 1 | 1 | 0 | ? | q(t − 1) | hold |

The “Hold” results means that the new value q(t) will be set to the previous value q(t-1).

The character alignment unit 230 detects errors when the combination of MSB and LSB results in a glitch of the entire control character. Such an error occurs when the MSB does not switch synchronously with the rest of the bits and refers to the misalignment of control characters.

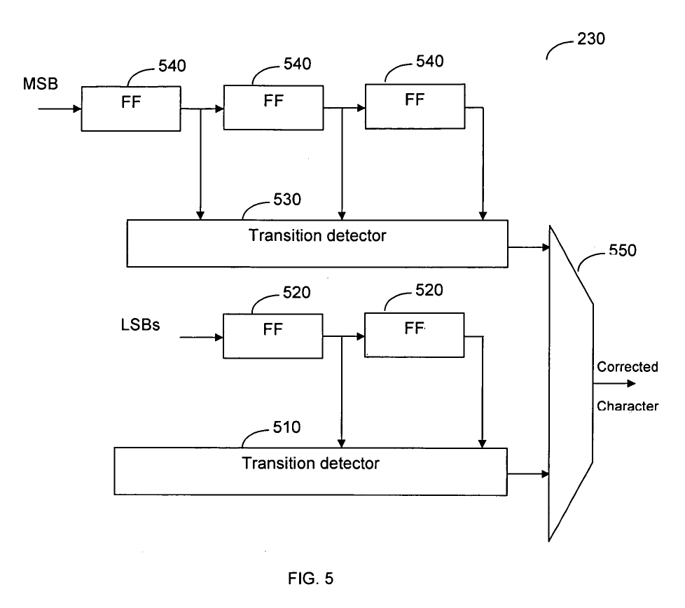

FIG. 5 shows an exemplary block diagram of the character alignment unit 230 constructed in accordance with an embodiment of the invention. The character alignment unit 230 detects misalignment between all bit transitions between the first control character (1101010100) and second character (0010101011) or between the third character (0b0101010100) and the forth character (0b010101011). The unit 230 receives a MSB input from the glitch filter 220 shown in FIG. 2) and 9 LSBs from the hamming distance filter 210. The transition detector 510 together with the flip-flops 520 detect misalignment in the transitions of the 9 LSB bits, i.e., if one of the LSBs transits to a different value prior to or after the other bits. Any detected misalignment transition is corrected by the transition detector 510. The transition detector 530 together with the flip-flops 540 determine if the MSB transits its value too late, too early, or on time relative to the LSBs. The transition detector 530 further outputs corrected MSB. The corrected LSBs and MSB are input to a multiplexer 550 that outputs the corrected control character.

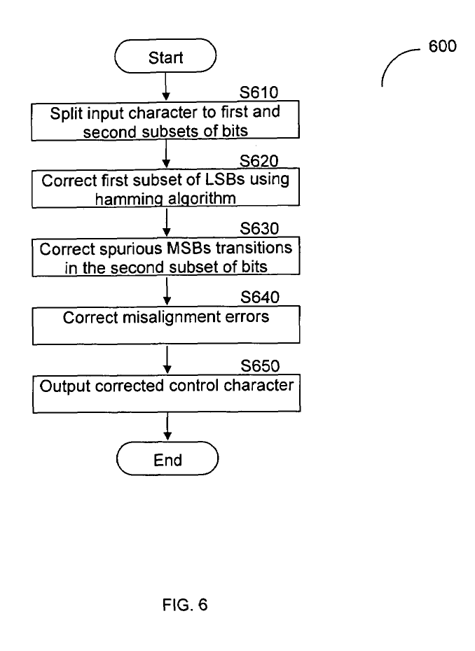

FIG. 6 shows an exemplary and non-limiting flowchart 600 describing a method for detecting and correcting control characters implemented in accordance with an embodiment of the invention. The steps of FIG. 6 may be performed in order or in parallel.

At S610 an input control character including M bits is split into a second subset of L bits and a first subset of U bits, where 1≦U≦L≦M, where the subset of bits for which a hamming distance filter is applicable does need not be contiguous. For example, hamming distance filter 210 can be applied for bit 0, 3, 4, 5, 7, and 9, if the character is defined in such way. In one embodiment, the first and second subsets of bits respectively include LSBs and MSBs of a control character. At S620, errors in the first set of LSBs are detected and corrected using a hamming algorithm, where the U LSBs have a minimum hamming distance greater than 1. In accordance with one embodiment, the input character is a TDMS control character, M equals 10, L equals 1, and U equals 9. As described in detail above, in such embodiment 4 error bits can be corrected using the hamming algorithm.

At S630, the second subset of L MSBs are processed to detect and correct errors results from spurious bit transitions. This is performed by checking if at least one bit of the L MSBs transits to an invalid value during n consecutive clock cycles. At S640, misaligned characters are detected and corrected by checking if the value of the corrected MSBs transit before or after the transition of the corrected LSBs. A transition can be one pattern of the character to another pattern, where both patterns are known a priori. At S650, a correct control character is output.

It should be appreciated by one of ordinary skill in the art that the invention described herein can significantly reduce the error rate of TDMS control characters. In addition, not all of the correction stages are required in order to improve the error rate. For example, in some cases the hamming distance can correct the error. Simulation results showing the percentage of errors corrected during different stages is provided in Table 4.

TABLE 4

| | % of corrected errors per stage | | | | |
|---|---|---|---|---|---|
| Total | Hamming | | 2 clock | | |
| number | distance | 1 clock | glitch | Character | |
| of errors | filter | glitch filter | filter | alignment | overall |
| 6550 | 85% | 58% | 10% | 17% | 95% |
| 992 | 89% | 78% | 8% | 22% | 98% |
| 101 | 89% | 91% | 0% | 100% | 100% |
| 11 | 82% | 100% | N/A | N/A | 100% |
| 122 | 91% | 82% | 0% | 50% | 99% |
| 1 | 100% | N/A | N/A | N/A | 100% |
| 29 | 93% | 50% | 0% | 0% | 97% |
| 330 | 88% | 87% | 0% | 20% | 99% |

The principles of the invention may be implemented in hardware, software, firmware or any combinations thereof. The software may be implemented as an application program tangibly embodied on a program storage unit or computer readable medium. The application program may be uploaded to, and executed by, a machine comprising any suitable architecture, for example a computer platform having hardware such as one or more central processing units (“CPUs”), a random access memory (“RAM”), and input/output (“I/O”) interfaces. The computer platform may also include an operating system and microinstruction code. The various processes and functions described herein may be either part of the microinstruction code or part of the application program, or any combination thereof, which may be executed by a CPU, whether or not such computer or processor is explicitly shown.

It is to be further understood that, because some of the constituent system components and methods depicted in the accompanying drawings are preferably implemented in software, the actual connections between the system components or the process function blocks may differ depending upon the manner in which the present invention is programmed. Given the teachings herein, one of ordinary skill in the pertinent art will be able to contemplate these and similar implementations or configurations of the present invention. All examples and conditional language recited herein are intended for pedagogical purposes to aid the reader in understanding the principles of the invention and the concepts contributed by the inventors to furthering the art, and are to be construed as being without limitation to such specifically recited examples and conditions.

All statements herein reciting principles, aspects, and embodiments of the invention, as well as specific examples thereof, are intended to encompass both structural and functional equivalents thereof. It is intended that such equivalents include both currently known equivalents as well as equivalents developed in the future, i.e., any elements developed that perform the same function, regardless of structure. Other hardware, conventional and/or custom, may also be included.

What we claim is:

1. An apparatus for detecting and correcting errors in control characters of a multimedia interface, comprising:
a hamming distance filter for detecting and correcting bits errors in a first subset of bits of an input control character including M bits; and
a glitch filter for detecting and correcting a second subset of bits being a complementary subset of bits of the input control character.

2. The apparatus of claim 1, further comprising:
a character alignment unit for detecting and correcting misalignment errors between the corrected first subset of bits and the corrected second subset of bits.

3. The apparatus of claim 1, wherein the multimedia interface is a high-definition multimedia interface (HDMI).

4. The apparatus of claim 3, wherein the control characters comprise at least transition minimized differential signaling (TMDS) control characters.

5. The apparatus of claim 4, wherein M equals 10, the first subset of bits includes 9 least significant bits of the input control character, and the second subset of bits includes a most significant bit.

6. The apparatus of claim 5, wherein the input control character has a predefined pattern.

7. The apparatus of claim 6, wherein the hamming filter compares the first subset of bits to a predefined pattern; and corrects the first subset of bits by replacing the first subset of bits with one of the predefined patterns having the smallest hamming distance to the first subset of bits.

8. The apparatus of claim 6, wherein the glitch filter detects spurious transitions of bits in the second subset of bits during at least one clock cycle.

9. The apparatus of claim 8, wherein the glitch filter comprises a plurality of glitch filters connected in cascade, wherein each of the plurality of glitch filters is capable of detecting spurious transitions of bits during a different number of clock cycles.

10. The apparatus of claim 2, wherein the character alignment unit detects errors when a combination of the corrected first subset of bits and the corrected second subset of bits results in a glitch of the entire input control character.

11. An method for detecting and correcting errors in control characters of a multimedia interface, comprising:
detecting and correcting bits errors in a first subset of bits of an input control character including M bits; and
detecting and correcting bits errors in a second subset of bits being a complementary subset of bits of the input control character.

12. The method of claim 11, further comprising:
detecting and correcting misalignment errors between the corrected first subset of bits and the corrected second subset of bits; and
outputting a corrected control character.

13. The method of claim 11, wherein the multimedia interface is a high-definition multimedia interface (HDMI).

14. The method of claim 13, wherein the control characters are at least transition minimized differential signaling (TMDS) control characters.

15. The method of claim 14, wherein M equals 10, the first subset of bits includes 9 least significant bits of the control character, and the second subset of bits includes a most significant bit.

16. The method of claim 15, wherein the control character has a predefined pattern.

17. The method of claim 16, wherein detecting and correcting bit errors in the first subset of bits, further comprising:
comparing the first subset of bits to one of the predefined patterns; and
replacing the first subset of bits with one of the predefined patterns having the smallest hamming distance to the first subset of bits, thereby outputting the corrected first subset of bits.

18. The method of claim 16, wherein detecting and correcting bit errors in the second subset of bits, further comprising:
detecting spurious transitions of bits in the second subset of bits during at least one clock cycle; and
changing the value of each spurious bit.

19. The method of claim 12, wherein detecting misalignment errors, further comprising:
detecting when a combination of the corrected first subset of bits and the corrected second subset of bits results in a glitch of the entire control character.

20. A computer readable medium having stored thereof computer executable code for detecting and correcting errors in control characters of a multimedia interface, comprising:
detecting and correcting bits errors in a first subset of bits of an input control character including M bits; and
detecting and correcting bits errors in a second subset of bits being a complementary subset of bits of the control character.
